(19) United States
(12) Patent Application Publication
(10) Pub. No.: US 2016/0266621 A1
(43) Pub. Date: Sep. 15, 2016

(54) ELECTRONIC DEVICE COOLING

(71) Applicant: Microsoft Technology Licensing, LLC, Redmond, WA (US)

(72) Inventors: Samuli Mäkinen, Salo (FI); Juuso Heiskanen, Kaarina (FI); Mikael Kontkanen, Ilmarinen (FI)

(21) Appl. No.: 14/657,438

(22) Filed: Mar. 13, 2015

(51) Int. Cl. G06F 1/20; H05K 7/20

(52) U.S. Cl. CPC G06F 1/203; H05K 7/20436

(57) ABSTRACT

An electronic device with passive internal cooling is disclosed. The electronic device comprises a printed wiring board (PWB), an electronic element operable to produce heat connected to the PWB, a movable heat transmission element, and a heat transmission interface. The electronic device is operable in a first state and a second state. In the first state the movable heat transmission element is configured to be in thermal contact with the heat transmission interface and the electronic element operable to produce heat, and in the second state there is a space between the movable heat transmission element and the heat transmission interface. The electronic device is configured to enter the first and second states via movement of the movable heat transmission element. A system and a method for cooling electronic devices are also disclosed.

### BACKGROUND

Electronic user devices such as mobile phones, tablets and computers have at least one processor which requires cooling. In most devices the CPU is cooled by fans or passive inbuilt cooling systems. The CPU can be connected to a heat sink which transfers heat to a fan through heat pipes. In case of passive cooling, dissipation of heat into the material inside the device or into the air is used.

### SUMMARY

The following presents a simplified summary of the disclosure in order to provide a basic understanding to the reader. This summary is provided to introduce a selection of concepts in a simplified form that are further described below in the Detailed Description. This summary is not intended to identify key features or essential features of the claimed subject matter, nor is it intended to be used to limit the scope of the claimed subject matter.

An electronic device with passive internal cooling is presented. The device comprises a movable heat transmission element which can switch positions and thereby cause the device to enter state 1 or state 2. In state 1, the movable element is in a position where it can transmit heat generated by e.g. a processor into a heat transmission interface. In state 2, the movable element is in a position with no thermal contact with the heat transmission interface. The device enters state 1 or 2 via movement of the movable element.

A system for cooling portable devices is also presented. The system comprises a portable device like the one described above and an external cooling interface. Connecting the device to the cooling interface can trigger the movement of the movable element and change the state of the device. The cooling element may conclude the chain of heat transmission from the processor. A method for cooling a processing unit in an electronic device is also presented.

Many of the attendant features will be more readily appreciated as the same becomes better understood by reference to the following detailed description considered in connection with the accompanying drawings.

### DESCRIPTION OF THE DRAWINGS

The present description will be better understood from the following detailed description read in light of the accompanying drawings, wherein:

FIG. 1A shows part of a portable device according to an embodiment;

FIG. 1B shows part of a portable device in a second configuration according to an embodiment;

FIG. 1C shows part of a portable device in a third configuration according to an embodiment;

FIG. 2 illustrates a system according to an embodiment;

FIG. 3 is a flow chart of a method according to an embodiment.

Like reference numerals are used to designate like parts in the accompanying drawings.

### DETAILED DESCRIPTION

The detailed description provided below in connection with the appended drawings is intended as a description of the present examples and is not intended to represent the only forms in which the present example may be constructed or utilized. However, the same or equivalent functions and sequences may be accomplished by different examples. The embodiments described below are not limited to implementations which solve any or all of the disadvantages of known devices and methods.

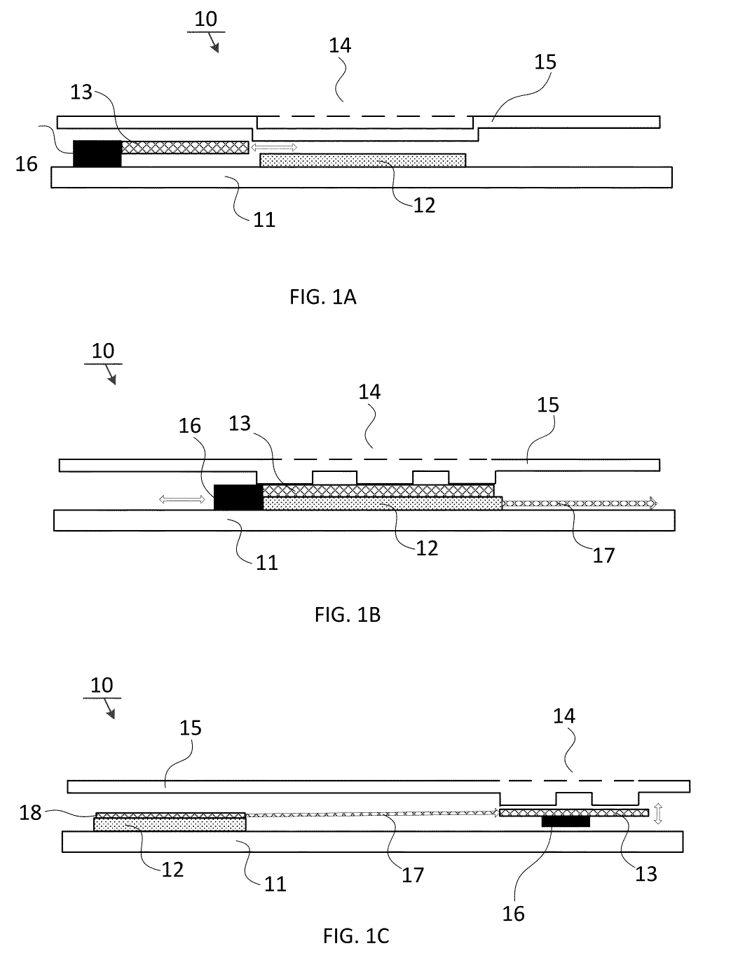

FIG. 1A shows part of a device 10 according to an example embodiment. The device 10 is an electronic device with passive internal cooling. As it is clear to a skilled person, the elements illustrated by this and the subsequent figures are demonstrated only schematically and do not necessarily represent shapes and proportions of actual elements of a device. As the device 10 is a device with passive internal cooling, it may be a device which does not include an active cooling system such as a fan. The device 10 may be, but is not limited to, a portable device, for example a mobile phone, a tablet, a music player, an electronic reader or a laptop computer with passive cooling.

The device 10 comprises a printed wiring board (PWB) 11, sometimes also referred to as printed circuit board, and an electronic element operable to produce heat 12 connected to it. The PWB 11 may also be a printed circuit board or a motherboard. The electronic element operable to produce heat 12 may be, for example, a processing unit, a central processing unit (CPU) of the device, or any other element that can generate heat when the device 10 is operational. The connection between the PWB 11 and the heat producing element 12 may be an electric connection.

The device 10 also comprises a movable heat transmission element 13 and a heat transmission interface 14. The movable heat transmission element 13 may comprise one or more of copper and graphite. The device 10 is operable in a first and a second state. In the first state the movable heat transmission element 13 is configured to be in thermal contact with the heat transmission interface 14 and the heat producing element 12. In the second state there is a space between the movable heat transmission element 13 and the heat transmission interface 14. FIG. 1A schematically illustrates the second state, and in FIG. 1B the device 10 is in the first state. The device 10 is configured to enter the first and second states via movement of the movable heat transmission element 13. In other words, the first state of the device 10 is when the heat transmission element 13 moves into a position where it has a thermal contact with the interface 14 and heat producing element 12. Accordingly, the second state is when the element 13 moves away from this position and is not in a thermal contact with the heat transmission interface 14.

While FIGS. 1A and 1B illustrate horizontal movement of the movable heat transmission element 13, the invention is not limited to such movement. The element 13 may, for example, move vertically, or according to various combinations of vertical and horizontal movement, expand and/or shrink or perform any other movement that allows it to be in and out of thermal contact with the heat transmission interface 14. The movable heat transmission element 13 can be in thermal contact with the heat producing element 12 permanently or in the first state only. In an embodiment, the heat transmission element 13 is in physical contact with the heat transmission interface 14 and the heat producing element 12 in the first state, which provides a thermal contact.

The device 10 may also comprise a casing 15, and the heat transmission interface 14 may include a region on the casing 15. For example, the heat transmission interface 14 may be a cavity in the casing 15, as shown on FIGS. 1A and 1B. The cavity may be flat as in FIG. 1A or notched as in FIG. 1B, or it may have any other shape which provides heat transmission from the element 13 in the first state and suits the movement pattern.

According to an embodiment, the device 10 may be connected to an external cooling interface (not shown on FIGS. 1A-1B). The first state can then be activated by this connection, and the second state can be activated when the device 10 is disconnected from the external cooling interface.

The device 10 according to any of the above embodiments can have a technical effect of improved cooling when such cooling is necessary by entering the first state, and maintaining the heat transmission interface 14 (that can be, for example, on the back panel of the device 10) unheated when the cooling is not needed by entering the second state.

In an embodiment, the device 10 further comprises a movement element 16 in physical contact with the movable heat transmission element 13. The movement element 16 can cause movement of the movable heat transmission element 13. The movement element 16 may be, but is not limited to, a mechanical gear, a magnet or a shape-memory alloy. The mechanical gear may be activated mechanically, the magnet may be moved by another magnet or by a ferromagnetic material, and the shape-like memory alloy may change its shape and thereby move the element 13.

In an embodiment, movement of the movable heat transmission element 13 can be caused by heat. For example, the movable heat transmission element 13 may comprise material that changes in volume in response to heat. The movement element 16 including a shape-memory alloy may also be used to cause movement of the heat transmission element 13 by heat. The shape-memory alloy may include, for example, a nickel-titanium alloy. The size of shape of the shape-memory alloy can change depending on its temperature, and this change may be reversible. In case of a nickel-titanium alloy, the change of shape can be caused by change of the crystalline structure between austenite and martensite. A technical effect of this embodiment may be responsive cooling when the heat producing element 12 overheats, and removal of thermal connection from the heat transmission interface 14 (which can occupy part of the device cover 15) when the interface 14 become too warm to comfortably use the device.

According to an embodiment, the passive internal cooling of the device 10 also comprises an additional heat transmission element 17. The additional heat transmission element 17 may be, for example, a heat pipe. The additional heat transmission element 17 may comprise graphite. The element 17 can be, for example, part of the passive cooling which takes place in both state 1 and state 2 of the device 10.

FIG. 1C illustrates an example embodiment wherein the movable heat transmission element 13 is in permanent thermal contact with the heat producing element 12 via the additional heat transmission element 17 (such as a heat pipe) and an optional third heat transmission element 18. When the first state is activated, the movement element 16 can place the movable heat transmission element 13 into contact with the heat transmission interface 14, and move it away when entering the second state. The structure in this embodiment may also be a combined heat transmission element comprising three parts (13, 18, and 17), wherein one part 18 is in direct contact with the heat producing element 12, and the other part 13 can move into contact with the heat transmission interface 14. The two parts (13, 18) are thermally connected via the third part 17. In this embodiment, the movable heat transmission element 13 is shown to move vertically. As it is clear to a skilled person, movement of the element 13 is not limited to vertical movement, and the three parts (13, 18, and 17) can be implemented as a single part, for example a copper tape with a movable part.

The embodiment illustrated in FIG. 1C can have all the technical effects of other embodiments described above, and additionally allows placing the heat transmission interface 14 and the heat producing element 12 in two independent locations in the device 10.

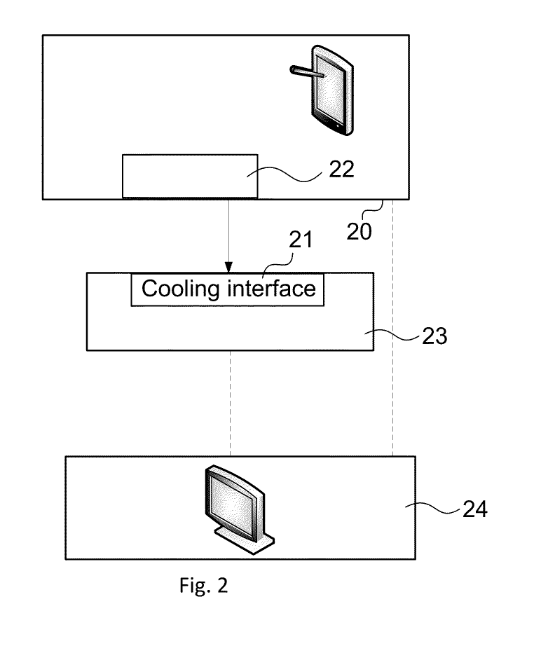

FIG. 2 shows a system according to an embodiment of the invention. The system comprises a portable device 20 with passive internal cooling and an external cooling interface 21 that can be connected to the portable device 20, as shown schematically by an arrow. The portable device 20 may be, but is not limited to, a mobile phone, a tablet, a music player, an electronic reader or a laptop computer with passive cooling. A touch screen tablet icon is added for exemplary purposes only.

The portable device 20 comprises a printed wiring board, a processing unit connected to the printed wiring board, a movable heat transmission element, and a heat transmission interface 22. In the system illustrated in FIG. 2 elements of the portable device 20 are not shown because they may not be visible from the outside, except for the heat transmission interface 22 that may include a region on the casing of the device 20.

The portable device 20 may be, for example, the device described above with reference to FIGS. 1A-1C. Similar to the described devices, the portable device 20 has a first state and a second state. In the first state the movable heat transmission element is in thermal contact with the heat transmission interface 22, and in the second state there is a space between the movable heat transmission element and the heat transmission interface 22.

The external cooling interface 21 comprises a triggering mechanism configured to trigger movement of the movable heat transmission element so that the first state of the portable device is activated when the portable device 20 is connected to the external cooling interface 21, and the second state of the portable device 20 is activated when the portable device is disconnected from the external cooling interface 21. In other words, when the portable device 20 is plugged in the cooling interface 21, the triggering mechanism of the cooling interface 21 makes the device 20 enter the first state in which the heat generated by the processing unit of the device 20 can be transferred to the external cooling interface 21 via the heat transmission element and the heat transmission interface 22. The triggering mechanism can depend on the movement principle of the movable heat transmission element in the device 20. For example, it can be a mechanical trigger which causes a mechanical gear to move the movable heat transmission element

In the example embodiment shown on FIG. 2, the external cooling interface 21 is part of an external device 23. The external device 23 which comprises the cooling interface 21 may be, but is not limited to, a charging unit or a docking station.

The system may also comprise a display unit 24 that can be connected to the portable device. The connection may be a direct connection or a connection via the external device 23.

The following paragraph is a non-limiting example of an implementation of the system described above. A portable device 20 can run resource-heavy tasks that force the processing unit to produce a substantial amount of heat, such as, for example, or rendering high-definition video. In this implementation, the device may be connected to a charger 23 and a display 24 when performing such tasks. When the device 20 is connected to the charger 23, the heat transmission interface 22 also thermally connects with the cooling interface 21 of the charger 23, and the device 20 enters the first state in which the movable heat transmission element is in a position of heat transfer from the processor to the cooling interface 21. The device 20 also connects to the display 24 and the information is displayed on a larger screen. The portable device 20 is cooled and charged at the same time.

A technical effect of one or more of the above embodiments can be that in such a system additional cooling is performed when the portable device 20 is connected to the external cooling interface 21 which allows uninterrupted charging of the device 20 without overheating the processing unit. When the portable device 20 is disconnected from the external cooling interface 21, it enters the second state in which the movable heat transmission element moves away from thermal contact with the heat transmission interface. This can lead to quick cooling of a region of casing of the device which had been used as a heat transmission interface, and helps to avoid the unpleasant heat on the fingers or palms of a user.

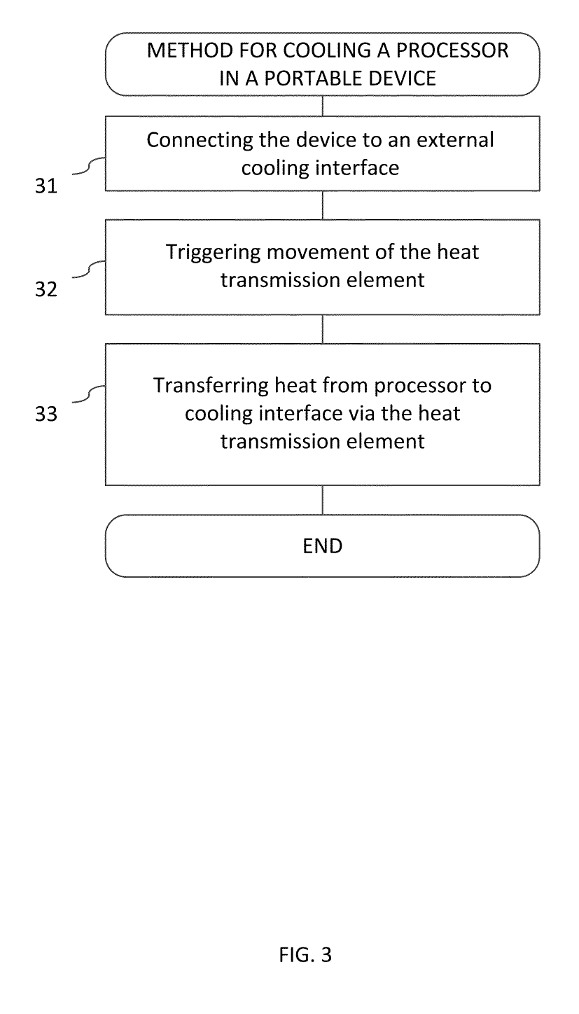

FIG. 3 is a flow chart for a method according to an aspect of the invention. The method is for cooling a processing unit in an electronic device e.g. with passive internal cooling. The device comprises: a printed wiring board, a processing unit connected to the printed wiring board, a movable heat transmission element, and a heat transmission interface. The method comprises connecting 31 the electronic device to an external cooling interface; triggering 32 movement of the movable heat transmission element into a position where the movable heat transmission element is in thermal connection with the heat transmission interface and the processing unit when the electronic device is connected to the external cooling interface; and transferring 33 heat generated by the processing unit to the cooling interface via the movable heat transmission element thermally connected to the heat transmission interface and the processing unit.

The external cooling interface may be, for example, part of a charging unit or a docking station. In an embodiment, the external cooling interface comprises a cooling region, and the method further comprises aligning the heat transmission interface with the cooling region when the electronic device is connected to the external cooling interface.

Triggering 32 the movement of the movable heat transmission element when the device is connected to the external heat transmission interface can include various techniques depending on the movement mechanism. For example, a mechanical gear of the electronic device can be activated, or a magnet or ferromagnetic of the electronic device can be brought into proximity of a magnet or ferromagnetic of the external cooling interface. The technique may also include affecting the shape of the shape memory alloy which is physically connected with the movable element.

The methods above can provide an effect of efficient electronic device cooling activated when the device is connected to a charger or docking station.

According to an aspect, an electronic device with passive internal cooling is provided. The electronic device comprises a printed wiring board, an electronic element operable to produce heat connected to the printed wiring board, a movable heat transmission element, and a heat transmission interface. The electronic device is operable in a first state or a second state, in the first state the movable heat transmission element is configured to be in thermal contact with the heat transmission interface and the electronic element operable to produce heat, and in the second state the movable heat transmission element is configured to be positioned with a space between the movable heat transmission element and the heat transmission interface.

In an embodiment, the electronic device is configured to enter the first and second states via movement of the movable heat transmission element.

In one embodiment, alternatively or in addition, the electronic element operable to produce heat is a processing unit.

In an embodiment, alternatively or in addition, the electronic device comprises a casing, wherein the heat transmission interface includes a region on the casing.

In an example embodiment, alternatively or in addition, the electronic device is configured to enter the first state via movement of the movable heat transmission element when the electronic device is connected to an external cooling interface, the electronic device is configured to enter the second state via movement of the movable heat transmission element when the electronic device is disconnected from the external cooling interface, and the movable heat transmission element is configured to transmit heat from the electronic element operable to produce heat to the external cooling interface via the heat transmission interface in the first state.

According to an embodiment, alternatively or in addition, the electronic device comprises a mechanical gear in physical contact with the movable heat transmission element, wherein movement of the movable heat transmission element is caused by activation of the mechanical gear.

In an embodiment, alternatively or in addition, the electronic device comprises a magnet in physical contact with the movable heat transmission element, wherein movement of the movable heat transmission element is caused by movement of the magnet.

In one embodiment, alternatively or in addition, the electronic device comprises a shape-memory alloy, wherein the movement of the movable heat transmission element is caused by a change of shape of the shape-memory alloy.

In an embodiment, alternatively or in addition, movement of the movable heat transmission element is caused by heat.

In an embodiment, alternatively or in addition, the electronic device further comprises an additional heat transmission element in thermal connection with the electronic element operable to produce heat, wherein the movable heat transmission element is in permanent thermal contact with the electronic element operable to produce heat via the additional heat transmission element.

In an example embodiment, alternatively or in addition, the additional heat transmission element comprises a heat pipe.

According to an aspect, a portable device cooling system is provided. The system comprises: a portable device with passive internal cooling, and an external cooling interface that can be connected to the portable device. In this system, the portable device comprises a printed wiring board, a processing unit connected to the printed wiring board, a movable heat transmission element, and a heat transmission interface; the portable device is operable in a first state or a second state; in the first state the movable heat transmission element is configured to be in thermal contact with the heat transmission interface and the processing unit, and in the second state there is a space between the movable heat transmission element and the heat transmission interface. The external cooling interface comprises a triggering mechanism configured to trigger movement of the movable heat transmission element so that the first state of the portable device is activated when the portable device is connected to the external cooling interface, and the second state of the portable device is activated when the portable device is disconnected from the external cooling interface.

In one embodiment, the system comprises a display unit that can be connected to the portable device.

In an embodiment, alternatively or in addition, the external cooling interface is part of a charging unit.

In an embodiment, alternatively or in addition, the external cooling interface is part of a docking station.

According to another aspect, a method for cooling a processing unit in an electronic device is presented. The electronic device comprises a printed wiring board, a processing unit connected to the printed wiring board, a movable heat transmission element, and a heat transmission interface. And the method comprises: connecting the electronic device to an external cooling interface, triggering movement of the movable heat transmission element into a position where the movable heat transmission element is in thermal connection with the heat transmission interface and the processing unit when the electronic device is connected to the external cooling interface, and transferring heat generated by the processing unit to the cooling interface via the movable heat transmission element thermally connected to the heat transmission interface and the processing unit.

In an embodiment, the external cooling interface comprises a cooling region, and the method further comprises aligning the heat transmission interface with the cooling region when the electronic device is connected to the external cooling interface.

In an embodiment, alternatively or in addition, the electronic device comprises a mechanical gear in physical contact with the movable heat transmission element, and triggering the movement of the movable heat transmission element comprises activating the mechanical gear of the electronic device when the electronic device is connected to the external cooling interface.

In an embodiment, alternatively or in addition, the electronic device comprises a magnet or a ferromagnetic in physical contact with the movable heat transmission element, the external cooling interface comprises a magnet or a ferromagnetic, and triggering the movement of the movable heat transmission element comprises bringing the magnet or ferromagnetic of the electronic device into proximity of the magnet or ferromagnetic of the external cooling interface when the electronic device is connected to the external cooling interface.

In one embodiment, alternatively or in addition, the electronic device comprises a shape-memory alloy in physical contact with the movable heat transmission element, and triggering the movement of the movable heat transmission element comprises affecting the shape of the shape memory alloy when the electronic device is connected to the external cooling interface.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

It will be understood that the benefits and advantages described above may relate to one embodiment or may relate to several embodiments. The embodiments are not limited to those that solve any or all of the stated problems or those that have any or all of the stated benefits and advantages. It will further be understood that reference to ‘an’ item refers to one or more of those items.

Aspects of any of the examples described above may be combined with aspects of any of the other examples described to form further examples without losing the effect sought.

The term ‘comprising’ is used herein to mean including the method blocks or elements identified, but that such blocks or elements do not comprise an exclusive list and a method or apparatus may contain additional blocks or elements.

It will be understood that the above description is given by way of example only and that various modifications may be made by those skilled in the art. The above specification, examples and data provide a complete description of the structure and use of exemplary embodiments. Although various embodiments have been described above with a certain degree of particularity, or with reference to one or more individual embodiments, those skilled in the art could make numerous alterations to the disclosed embodiments without departing from the spirit or scope of this specification.

1. An electronic device with passive internal cooling, the electronic device comprising:
a printed wiring board,
an electronic element operable to produce heat connected to the printed wiring board, a movable heat transmission element, and
a heat transmission interface; wherein
the electronic device is operable in a first state or a second state,
in the first state the movable heat transmission element is configured to be in thermal contact with the heat transmission interface and the electronic element operable to produce heat, and
in the second state the movable heat transmission element is configured to be positioned with a space between the movable heat transmission element and the heat transmission interface.

2. An electronic device as claimed in claim 1, configured to enter the first and second states via movement of the movable heat transmission element.

3. An electronic device as claimed in claim 1, wherein the electronic element operable to produce heat is a processing unit.

4. An electronic device as claimed in claim 1 comprising a casing, wherein the heat transmission interface includes a region on the casing.

5. An electronic device as claimed in claim 1, wherein:
the electronic device is configured to enter the first state via movement of the movable heat transmission element when the electronic device is connected to an external cooling interface,
the electronic device is configured to enter the second state via movement of the movable heat transmission element when the electronic device is disconnected from the external cooling interface, and
the movable heat transmission element is configured to transmit heat from the electronic element operable to produce heat to the external cooling interface via the heat transmission interface in the first state.

6. An electronic device as claimed in claim 1 comprising a mechanical gear in physical contact with the movable heat transmission element, wherein movement of the movable heat transmission element is caused by activation of the mechanical gear.

7. An electronic device as claimed in claim 1 comprising a magnet in physical contact with the movable heat transmission element, wherein movement of the movable heat transmission element is caused by movement of the magnet.

8. An electronic device as claimed in claim 1 comprising a shape-memory alloy, wherein the movement of the movable heat transmission element is caused by a change of shape of the shape-memory alloy.

9. An electronic device as claimed in claim 1, wherein movement of the movable heat transmission element is caused by heat.

10. An electronic device as claimed in claim 1 further comprising an additional heat transmission element in thermal connection with the electronic element operable to produce heat, wherein the movable heat transmission element is in permanent thermal contact with the electronic element operable to produce heat via the additional heat transmission element.

11. An electronic device as claimed in claim 10, wherein the additional heat transmission element comprises a heat pipe.

12. A portable device cooling system, comprising:
a portable device with passive internal cooling, and
an external cooling interface that can be connected to the portable device, wherein:
the portable device comprises a printed wiring board, a processing unit connected to the printed wiring board, a movable heat transmission element, and a heat transmission interface;
the portable device is operable in a first state or a second state;
in the first state the movable heat transmission element is configured to be in thermal contact with the heat transmission interface and the processing unit, and in the second state there is a space between the movable heat transmission element and the heat transmission interface;
the external cooling interface comprises a triggering mechanism configured to trigger movement of the movable heat transmission element so that the first state of the portable device is activated when the portable device is connected to the external cooling interface, and the second state of the portable device is activated when the portable device is disconnected from the external cooling interface.

13. A system as claimed in claim 12 comprising a display unit that can be connected to the portable device.

14. A system as claimed in claim 12, wherein the external cooling interface is part of a charging unit.

15. A system as claimed in claim 12, wherein the external cooling interface is part of a docking station.

16. A method for cooling a processing unit in an electronic device, the electronic device comprising: a printed wiring board, a processing unit connected to the printed wiring board, a movable heat transmission element, and a heat transmission interface;
wherein the method comprises:
connecting the electronic device to an external cooling interface,
triggering movement of the movable heat transmission element into a position where the movable heat transmission element is in thermal connection with the heat transmission interface and the processing unit when the electronic device is connected to the external cooling interface, and
transferring heat generated by the processing unit to the cooling interface via the movable heat transmission element thermally connected to the heat transmission interface and the processing unit.

17. A method as claimed in claim 16, wherein the external cooling interface comprises a cooling region, and the method further comprises aligning the heat transmission interface with the cooling region when the electronic device is connected to the external cooling interface.

18. A method as claimed in claim 16, wherein:
the electronic device comprises a mechanical gear in physical contact with the movable heat transmission element, and
triggering the movement of the movable heat transmission element comprises activating the mechanical gear of the electronic device when the electronic device is connected to the external cooling interface.

19. A method as claimed in claim 16, wherein:
the electronic device comprises a magnet or a ferromagnetic in physical contact with the movable heat transmission element,
the external cooling interface comprises a magnet or a ferromagnetic, and triggering the movement of the movable heat transmission element comprises bringing the magnet or ferromagnetic of the electronic device into proximity of the magnet or ferromagnetic of the external cooling interface when the electronic device is connected to the external cooling interface.

20. A method as claimed in claim 16, wherein:
the electronic device comprises a shape-memory alloy in physical contact with the movable heat transmission element, and
triggering the movement of the movable heat transmission element comprises affecting the shape of the shape memory alloy when the electronic device is connected to the external cooling interface.
